(19) United States
(12) Patent Application Publication
(10) Pub. No.: US 2021/0151536 A1
(43) Pub. Date: May 20, 2021

(54) DISPLAY DEVICE AND MANUFACTURING METHOD THEREOF

(71) Applicant: Japan Display Inc., Tokyo (JP)

(72) Inventor: Yohei YAMAGUCHI, Tokyo (JP)

(73) Assignee: Japan Display Inc., Tokyo (JP)

(21) Appl. No.: 17/161,709

(22) Filed: Jan. 29, 2021

Related U.S. Application Data
(63) Continuation of application No. PCT/JP2019/027086, filed on Jul. 9, 2019.

(30) Foreign Application Priority Data
Aug. 10, 2018 (JP) 2018-151624

(51) Int. Cl. H01L 27/32; H01L 29/786

(52) U.S. Cl. CPC H01L 27/3258; H01L 29/78651; H01L 2227/323; H01L 29/78618; H01L 29/7869

(57) ABSTRACT

Each of the plurality of thin film transistors is of a bottom gate type and including: a gate electrode; a gate insulating film covering the gate electrode; an oxide semiconductor layer on the gate insulating film; a silicon oxide in contact with a first upper surface region of the oxide semiconductor layer; a silicon nitride in contact with a second upper surface region of the oxide semiconductor layer; and a source electrode and a drain electrode above the gate insulating film. The second upper surface region is adjacent to each of both sides of the first upper surface region in a direction between the source electrode and the drain electrode. The oxide semiconductor layer includes a semiconductor portion directly below the silicon oxide and a conductive portion directly below the silicon nitride.

### CROSS-REFERENCE TO RELATED APPLICATION

This application is a continuation application of International Application PCT/JP2019/027086 filed on Jul. 9, 2019, which claims priority from Japanese patent application JP2018-151624 filed on Aug. 10, 2018. The contents of these applications are incorporated herein by reference in their entirety.

### BACKGROUND

### 1. Field

The disclosure relates to a display device and a method of manufacturing the same.

### 2. Description of the Related Art

Thin film transistors (TFTs) using low-temperature polysilicon have been used for organic electroluminescent displays and high-definition liquid crystal displays because of their high driving ability and high carrier mobility, but their off-current is high, making it difficult to suppress leakage current. Therefore, in recent years, TFTs using oxide semiconductors have been developed (JP No. 2016-100521A and JP No. 2012-104639A).

In a bottom gate type TFT, a metal film is etched over a semiconductor layer to form a source electrode and a drain electrode. Chlorine gas, which is frequently used in metal etching, has a small etching selectivity between a metal and a semiconductor, and therefore, unnecessary etching of the semiconductor layer proceeds. Specifically, at the portions adjacent to the source electrode and the drain electrode, the film thickness of the semiconductor layer is greatly made uneven. The uneven film thickness has a large impact on the characteristics of the oxide semiconductor TFT, because of low carrier mobility, despite the low off-current.

### SUMMARY

The disclosure aims at suppressing the unevenness of the thickness of the oxide semiconductor layer.

A display device includes a plurality of thin film transistors configured to control displaying images. Each of the plurality of thin film transistors being of a bottom gate type and including: a gate electrode; a gate insulating film covering the gate electrode; an oxide semiconductor layer on the gate insulating film; a silicon oxide in contact with a first upper surface region of the oxide semiconductor layer; a silicon nitride in contact with a second upper surface region of the oxide semiconductor layer; and a source electrode and a drain electrode above the gate insulating film. The second upper surface region is adjacent to each of both sides of the first upper surface region in a direction between the source electrode and the drain electrode. The oxide semiconductor layer includes a semiconductor portion directly below the silicon oxide and a conductive portion directly below the silicon nitride.

According to the disclosure, the second upper surface region, which the reducing agent layer is in contact with, is adjacent to each of both sides of the first upper surface region, which the oxidizing agent layer is in contact with. The semiconductor portion oxidized from the first upper surface region is not adjacent to the source electrode and the drain electrode. This suppresses unevenness, at the portion adjacent to the first upper surface region, of the film thickness of the oxide semiconductor layer.

A method of manufacturing a display device includes: forming a gate electrode; forming a gate insulating film to cover the gate electrode; forming an oxide semiconductor layer on the gate insulating film; forming a source electrode and a drain electrode, through deposition and etching on the oxide semiconductor layer, except in the first upper surface region and the second upper surface region of the oxide semiconductor layer; forming an oxidizing agent layer in contact with the first upper surface region of the oxide semiconductor layer, and oxidizing the oxide semiconductor layer in the first upper surface region; and forming a reducing agent layer in contact with the second upper surface region of the oxide semiconductor layer, and reducing the oxide semiconductor layer in the second upper surface region. The second upper surface region is adjacent to each of both sides of the first upper surface region in a direction between the source electrode and the drain electrode.

According to the disclosure, the second upper surface region, which the reducing agent layer is in contact with, is adjacent to each of both sides of the first upper surface region, which the oxidizing agent layer is in contact with. The first upper surface region, to be oxidized by the oxidizing agent layer, is not adjacent to the source electrode and the drain electrode. This suppresses unevenness formed by etching, at the portion adjacent to the first upper surface region, of the film thickness of the oxide semiconductor layer.

### BRIEF DESCRIPTION OF THE DRAWINGS

FIG. 1 is a plan view of a display device according to a first embodiment.

FIG. 2 is a circuit diagram of the display device.

FIG. 3 is a plan view of an element structure of each pixel.

FIG. 4 is a schematic view of a cross section of the display device in FIG. 1.

FIG. 5 is a detailed cross-sectional view of a thin film transistor.

FIG. 6 is a detailed plan view of the thin film transistor.

FIG. 7 is a detailed cross-sectional view of a thin film transistor of a display device according to a modification of the first embodiment.

FIG. 8 is a detailed cross-sectional view of a thin film transistor of the display device according to a second embodiment.

FIG. 9 is a detailed plan view of the thin film transistor.

FIG. 10 is a detailed cross-sectional view of a thin film transistor of the display device according to the third embodiment.

FIG. 11 is a cross-sectional view of a display device according to a fourth embodiment.

FIG. 12 is a diagram of an overall circuit of the display device.

FIG. 13 is a diagram of a circuit configuration of a pixel in FIG. 12.

### DETAILED DESCRIPTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

### First Embodiment

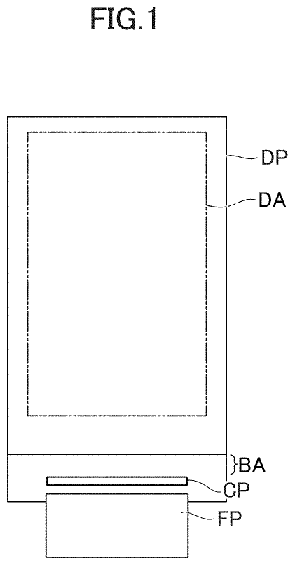

FIG. 1 is a plan view of a display device according to a first embodiment. The display device is practically used by being folded; FIG. 1 is a development view before folding the display device. The display device includes a display DP. The display DP has flexibility and is foldable at a bending support area BA outside a display area DA where images are displayed. An integrated circuit chip CP configured to drive elements for displaying images is mounted on the display DP. A flexible printed circuit board FP is connected to the display DP outside the display area DA. The display device may be an organic electroluminescent display device. In the display area DA, a full-color image is displayed by combining pixels (sub-pixels) of some colors such as red, green, and blue.

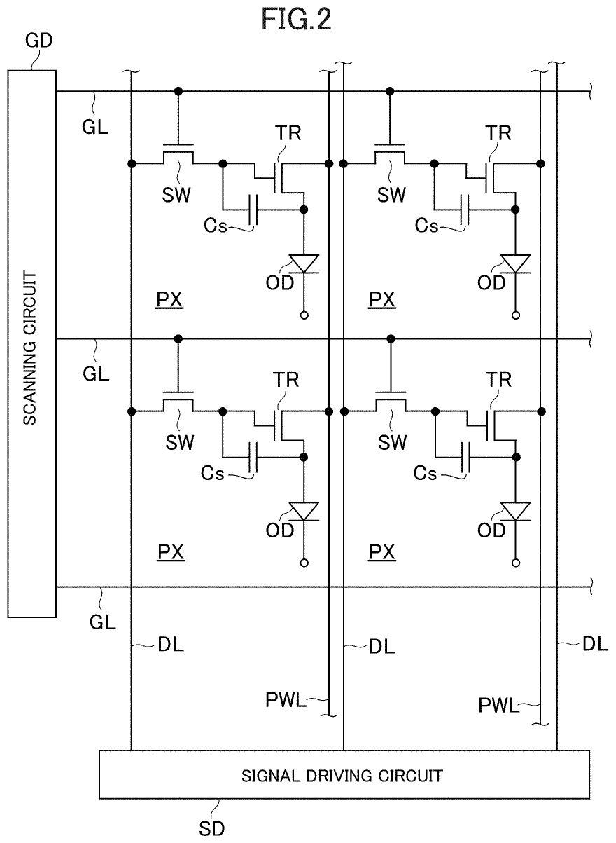

FIG. 2 is a circuit diagram of the display device. The circuit has a plurality of scanning lines GL connected to a scanning circuit GD, and a plurality of signal lines DL connected to a signal driving circuit SD. The signal driving circuit SD is disposed in the integrated circuit chip CP in FIG. 1. An area surrounded by two adjacent scanning lines GL and two adjacent signal lines DL is a pixel PX. The pixel PX includes a thin film transistor TR and a switching element SW as driving transistors, and a holding capacitor Cs. By applying gate voltage to the scanning line GL, the switching element SW is turned ON, a video signal is supplied from the signal line DL, and a charge is accumulated in the holding capacitance Cs. By accumulating the charge in the holding capacitance Cs, the thin film transistor TR is turned ON to pass a current from the power supply line PWL to the light emitting element OD. The current causes the light-emitting element OD to emit light.

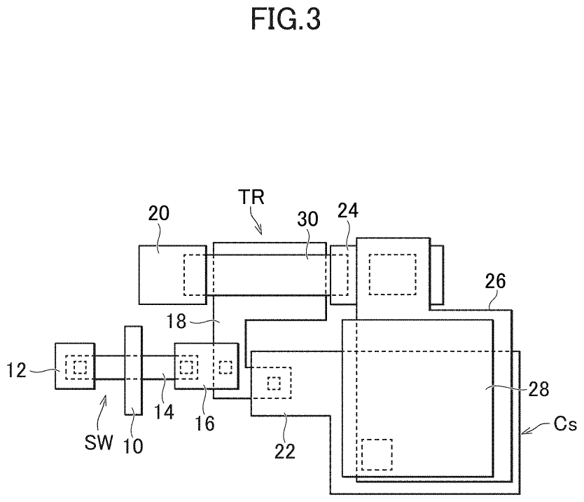

FIG. 3 is a plan view of an element structure of each pixel. Part of the scanning line GL in FIG. 2 is a gate electrode 10 of the switching element SW (e.g., thin film transistor). Part of the signal line DL in FIG. 2 is one source/drain electrode 12 (one of the source electrode and the drain electrode) of the switching element SW. A semiconductor layer 14 of the switching element SW is mainly made of polysilicon. Incidentally, a thin film transistor using low-temperature polysilicon has high electron mobility but has difficulty to suppress off-current due to high leakage current.

Another source/drain electrode 16 (another of the source electrode and the drain electrode) of the switching element SW is connected to a gate electrode 18 of the thin film transistor TR. Part of the power line PWL is one source/drain electrodes 20 (one of the source electrode and the drain electrode) of the thin film transistor TR.

The gate electrode 18 of the thin film transistor TR is connected to the first capacitor electrode 22. Another source/drain electrode 24 (another of the source electrode and the drain electrode) of the thin film transistor TR is connected to the second capacitor electrode 26. The first capacitance electrode 22 and the second capacitance electrode 26 are opposed to each other, constituting the holding capacitance Cs. The second capacitor electrode 26 is connected to the pixel electrode 28. The thin film transistor TR includes an oxide semiconductor layer 30.

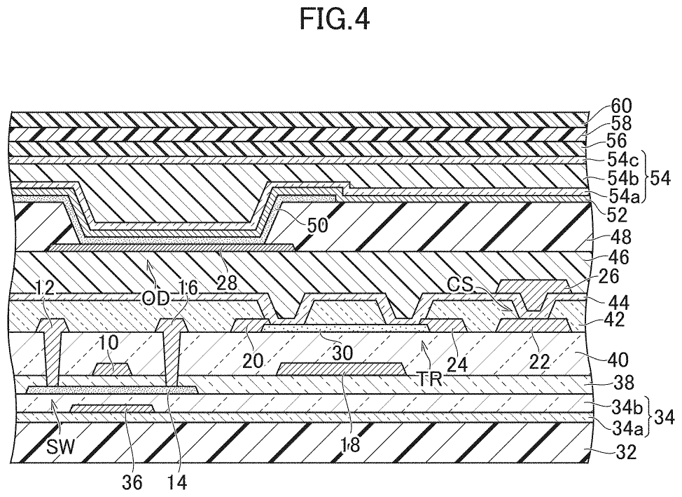

FIG. 4 is a schematic view of a cross section of the display device in FIG. 1. A substrate 32 is made of polyimide. However, any other resin material may be used if it is a base material having sufficient flexibility for forming a sheet display or a flexible display. A reinforcing film may be attached to the back of the substrate 32 via a pressure-sensitive adhesive.

An undercoat layer 34 is laminated on the substrate 32. The undercoat layer 34 includes a silicon oxide film 34a and a silicon oxide film 34b. The lower silicon oxide film 34a is for adhesion improvement with the substrate 32; the upper silicon oxide film 34b is for a block film to prevent the hydrogen atoms from being diffused into the semiconductor layer 14 of the switching element SW; the structure is not particularly limited hereto, may further include a lamination, or may be a single layer.

An additional film 36 is disposed below the switching element SW, for suppressing characteristic change due to penetration of light from the channel back surface, or for imparting a back-gate effect. Here, after the silicon oxide film 34a is formed, the additional film 36 is formed in an island shape in accordance with the place where the switching element SW is formed, and then the silicon oxide film 34b is laminated, so that the additional film 36 is sealed in the undercoat layer 34, however, this is not limiting, and the additional film 36 may be formed first on the substrate 32, and then the undercoat layer 34 may be formed.

The switching element SW is formed on the undercoat layer 34. Polysilicon thin film transistors are exemplified here, but only N-channel transistors are shown, and P-channel transistors may be formed at the same time. The semiconductor layer 14 of the switching element SW has a structure in which a low concentration impurity region is provided between the channel region and the source/drain region. A silicon oxide film is used here for the gate insulating film 38.

An insulating film 40 (a silicon oxide film and a silicon nitride film) is laminated on the gate electrode 10. The source/drain electrodes 12, 16 are formed, penetrating the insulating film 40. Here, a three-layer laminated structure of Ti, Al, and Ti is employed. The switching element SW is of a top gate type with the gate electrode 10 above the semiconductor layer 14.

The gate electrode 18 of the thin film transistor TR is in the same layer position as the gate electrode 10 of the switching element SW. The insulating film 40 is an interlayer insulating film covering the gate electrode 10 of the switching element SW and is also a gate insulating film of the thin film transistor TR. The oxide semiconductor layer 30 is above the gate electrode 18. The oxide semiconductor layer 30 is formed on the insulating film 40. A pair of source/drain electrodes 20, 24 (source electrode, drain electrode) are also formed on the insulating film 40. The pair of source/drain electrodes 20, 24 are also on the ends of the oxide semiconductor layer 30.

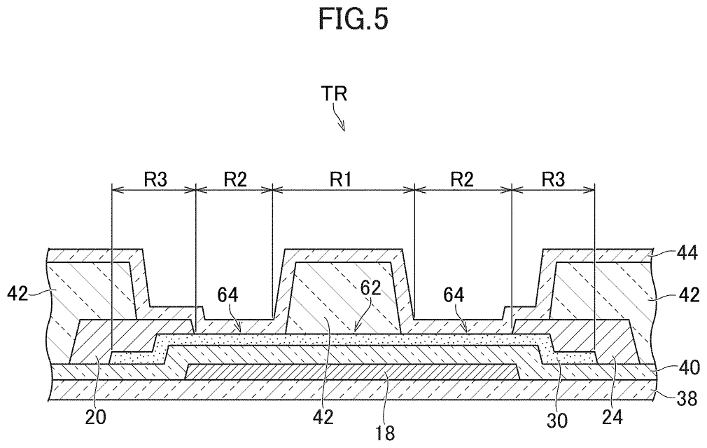

The thin film transistor TR has the oxide semiconductor layer 30 as a channel region, enabling reduction of current variation. The thin film transistor TR is at a layer position higher than the switching element SW. Therefore, the thin film transistor TR, formed later than the switching element SW, is free from effect by heat generated when the semiconductor layer 14 is formed from low-temperature polysilicon. Details of the thin film transistor TR will be described later (FIG. 5).

The first capacitor electrode 22 is also formed on the insulating film 40. An oxidizing agent layer 42 and a reducing agent layer 44 are laminated, covering the thin film transistor TR and the first capacitor electrode 22. The second capacitor electrode 26 is formed on them. The oxidizing agent layer 42 and the reducing agent layer 44 are dielectrics of the storage capacitor Cs in FIG. 2.

A planarization organic film 46 is provided, covering the reducing agent layer 44 and the second capacitor electrode 26. The planarization organic film 46 is formed from resin such as photosensitive acrylic because of superiority in flatness to inorganic insulating materials formed by CVD (Chemical Vapor Deposition).

The pixel electrode 28 is on the planarizing organic film 46. The pixel electrode 28 is formed as a reflective electrode, and has a three-layer laminated structure of an indium zinc oxide film, an Ag film, and an indium zinc oxide film. Here, the indium zinc oxide film may be replaced with an indium tin oxide film.

An insulating organic film 48, called a bank (rib), serving as a partition wall between adjacent pixel regions, is formed on the planarizing organic film 46 and on the periphery of the pixel electrode 28. The insulating organic film 48 may be made from photosensitive acrylic, just like the planarizing organic film 46. The insulating organic film 48 has an opening to expose a surface of the pixel electrode 28 as a light emitting region; its open end should be a gently tapered shape. An open end in a steep shape leads to poor coverage of the organic electroluminescent layer 50 formed thereon.

There is an organic electroluminescent layer 50, made of an organic material, on the pixel electrode 28. The organic electroluminescent layer 50 may be a single layer, or may have a structure in which a hole transport layer, a light emitting layer, and an electron transport layer are laminated in this order from the pixel electrode 28 side. These layers may be formed by evaporation, may be formed by coating after dispersion in a solvent, may be formed selectively on the pixel electrodes 28 (respective sub-pixels), or may be continuously formed over the entire surface covering the display area DA. In the case of the continuous formation, white light is obtained in all sub-pixels, and a desired color wavelength portion is extracted by a color filter (not shown).

There is a counter electrode 52 on the organic electroluminescent layer 50. Here, a top emission structure is employed, and the counter electrode 52 is transparent. For example, an Mg layer and an Ag layer are formed as a film thin enough to transmit the light emitted from the organic electroluminescence layer 50. According to the order of formation of the organic electroluminescent layer 50 described above, the pixel electrode 28 is an anode, whereas the counter electrode 52 is a cathode. The pixel electrodes 28, the counter electrode 52, the organic electroluminescent layer 50 interposed between a central portion of each pixel electrode 28, and the counter electrode 52 constitute a light emitting element OD.

There is a sealing layer 54 on the counter electrode 52. The sealing layer 54 has a feature of preventing moisture from entering from the outside into the organic electroluminescent layer 50 formed earlier, requiring high gas barrier properties. The sealing layer 54 has a laminated structure of a sealing organic film 54b and a pair of sealed inorganic films 54a, 54c (e.g., silicon nitride films) sandwiching it from above and below. The pair of sealing inorganic films 54a, 54c overlap with each other in contact with each other around the sealing organic film 54b. A silicon oxide film or an amorphous silicon layer may be provided between the sealing inorganic films 54a, 54c and the sealing organic film 54b for improving adhesion. A reinforcing organic film 56 is laminated on the sealing layer 54. A polarizing plate 60 is attached to the reinforcing organic film 56 via an adhesive layer 58. The polarizing plate 60 may be a circularly polarized plate.

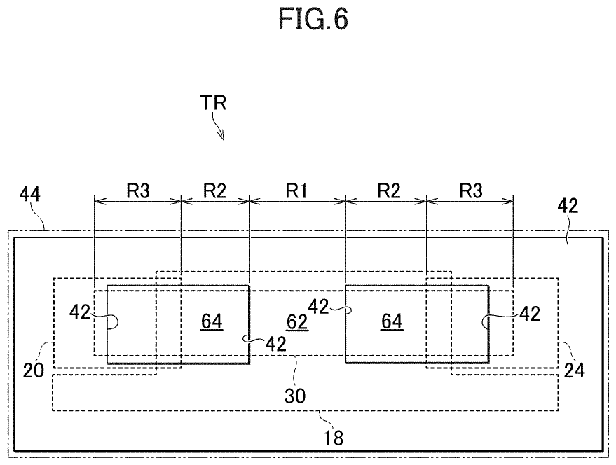

FIG. 5 is a detailed cross-sectional view of a thin film transistor TR. FIG. 6 is a detailed plan view of the thin film transistor TR.

The display device has a plurality of thin film transistors TR configured to control displaying images. Each of the plurality of thin film transistors TR is of a bottom gate type. The thin film transistor TR has a gate electrode 18. The thin film transistor TR has an insulating film 40 covering the gate electrode 18. The thin film transistor TR has a pair of source/drain electrodes 20, 24 (source electrode, drain electrode) above the insulating film 40.

The thin film transistor TR has the oxide semiconductor layer 30 over the insulating film 40. The oxide semiconductor layer 30 is made of, for example, indium-gallium-zinc-oxygen (IGZO). This kind of thin film transistor TR has low off-current characteristics.

The oxide semiconductor layer 30 has a first upper surface region R1. The oxidizing agent layer 42 is in contact with the first upper surface region R1 of the oxide semiconductor layer 30. The oxidizing agent layer 42 contains silicon oxide. The oxide semiconductor layer 30 includes a semiconductor portion 62 oxidized from the first upper surface region R1 by the oxidizing agent layer 42. The semiconductor portion 62 exhibits semiconductor properties because of decrease in electrons by oxidation, enabling transistor operation. The oxidizing agent layer 42 is also on the pair of source/drain electrodes 20, 24 (source electrode, drain electrode).

The oxide semiconductor layer 30 has a second upper surface region R2. The second upper surface region R2 is adjacent to each of both sides of the first upper surface region R1 in the direction between the pair of source/drain electrodes 20, 24 (source electrode, drain electrode). The reducing agent layer 44 is in contact with the second upper surface region R2 of the oxide semiconductor layer 30. The reducing agent layer 44 contains silicon nitride with hydrogen. The hydrogen may be contained depending on film formation conditions or may be originally contained in the silicon nitride. The hydrogen undergoes a reduction reaction that pulls out oxygen by combining with the oxygen. The oxide semiconductor layer 30 includes a conductive portion 64 reduced from the second upper surface region R2 by the reducing agent layer 44. The conductive portion 64, in which the oxygen is removed by reduction to increase electrons as carriers, is made conductive. The reducing agent layer 44 is also on the oxidizing agent layer 42.

The oxide semiconductor layer 30 has a pair of third upper surface regions R3 sandwiching the first upper surface region R1 and the second upper surface region R2. The pair of source/drain electrodes 20, 24 are in contact with and electrically connected to the respective pair of third upper surface regions R3. The pair of source/drain electrodes 20, 24 are made of metal. The oxide semiconductor layer 30 is reduced by the metal and is electrically made conductive, on the pair of third upper surface regions R3.

The oxide semiconductor layer 30 is higher in oxygen concentration at the semiconductor portion 62 and lower in hydrogen concentration than at the conductive portion 64. Additionally, the conductive portion 64 is higher in electrical conductivity than the semiconductor portion 62. Further, the oxide semiconductor layer 30, directly below the third upper surface region R3, hardly passes electricity, whereby dominantly electrical conduction is generated at the source/drain electrodes 20, 24.

According to the embodiment, the second upper surface region R2, which the reducing agent layer 44 is in contact with, is adjacent to each of both sides of the first upper surface region R1, which the oxidizing agent layer 42 is in contact with. The semiconductor portion 62, oxidized from the first upper surface region R1, is not adjacent to the pair of source/drain electrodes 20, 24. This can suppress unevenness of the film thickness of the oxide semiconductor layer 30, at the portion adjacent to the first upper surface region R1.

### [Method of Manufacturing Display Device]

In the manufacturing method of the display device, as shown in FIG. 5, the gate electrode 18 is formed. The insulating film 40 is formed, covering the gate electrode 18. The oxide semiconductor layer 30 is formed on the insulating film 40.

Through film formation and etching of a metal film on the oxide semiconductor layer 30, the pair of source/drain electrodes 20, 24 are formed, except in the first upper surface region R1 and the second upper surface region R2. The pair of source/drain electrodes 20, 24 are formed of metal; the etching is performed using a chlorine-based gas. By using the chlorine-based gas, the etching rates of the metal and the semiconductor (oxide semiconductor) get closer to each other. Besides, the film thickness of the semiconductor tends to be uneven at the portion adjacent to an etching mask. However, the second upper surface region R2 is adjacent to each of both sides of the first upper surface region R1 in the direction between the pair of source/drain electrodes 20, 24. Thus, the pair of source/drain electrodes 20, 24, serving as the etching mask of the oxide semiconductor layer 30, is away from the first upper surface region R1.

The oxidizing agent layer 42 is formed in contact with the first upper surface region R1 and the second upper surface region R2 of the oxide semiconductor layer 30. The formation of the oxidizing agent layer 42 includes dry etching using a fluorine-based gas. By using the fluorine-based gas, high etching selectivity can be obtained, due to difference in the etching rates of the metal and the semiconductor (oxide semiconductor).

By the oxidizing agent layer 42, the oxide semiconductor layer 30 is oxidized in the first upper surface region R1 and the second upper surface region R2. Thus, due to decrease in electrons by the oxidation, the semiconductor portion 62 with semiconducting properties is formed. The oxidizing agent layer 42 is formed also on the pair of source/drain electrodes 20, 24.

The reducing agent layer 44 is formed in contact with the second upper surface region R2 of the oxide semiconductor layer 30. The reducing agent layer 44 is formed also on the oxidizing agent layer 42. The oxide semiconductor layer 30 is reduced in the second upper surface region R2 by the reducing agent layer 44.

According to the embodiment, the first upper surface region R1 to be oxidized by the oxidizing agent layer 42 is not adjacent to the pair of source/drain electrodes 20, 24. This can suppress unevenness, of the film thickness of the oxide semiconductor layer 30, by etching, at the portion adjacent to the first upper surface region R1. The film thickness is even at the semiconductor portion 62, stabilizing the characteristics as a semiconductor. The conductive portion 64, even if the film thickness becomes uneven, does not give a great impact on the characteristics of the thin film transistor TR, due to the portion of being conductive.

### Modification of the First Embodiment

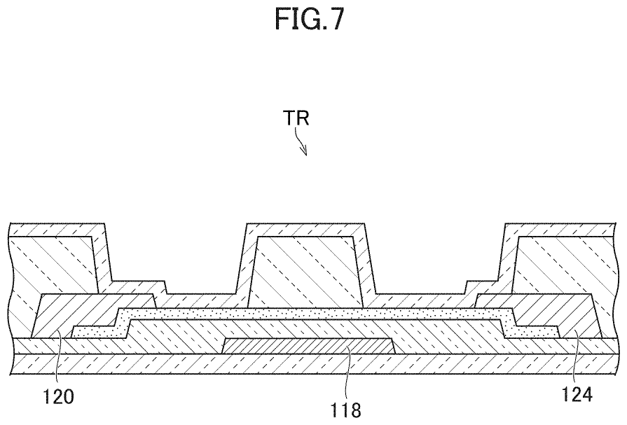

FIG. 7 is a detailed cross-sectional view of a thin film transistor TR of a display device according to a modification of the first embodiment. In the example, the gate electrode 118 does not overlap with the source/drain electrodes 120, 124 (source electrode, drain electrode). This enables reduction or elimination of the capacitance formed between the gate electrode 118 and the source/drain electrodes 120, 124. What is explained in the first embodiment is applicable hereto.

### Second Embodiment

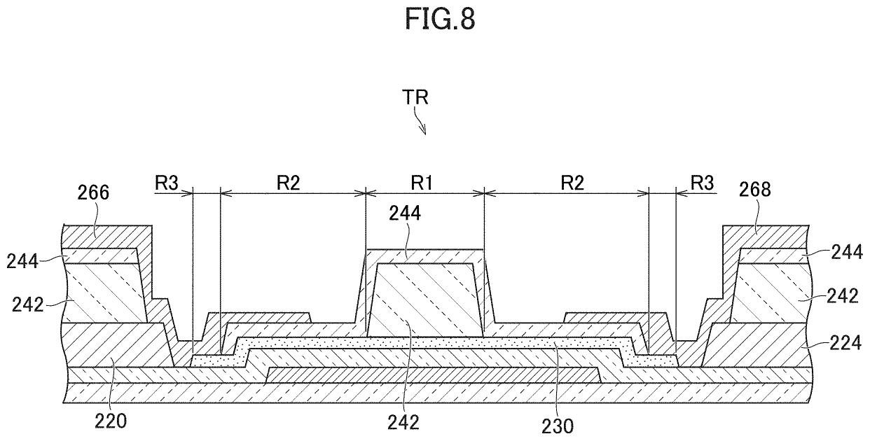

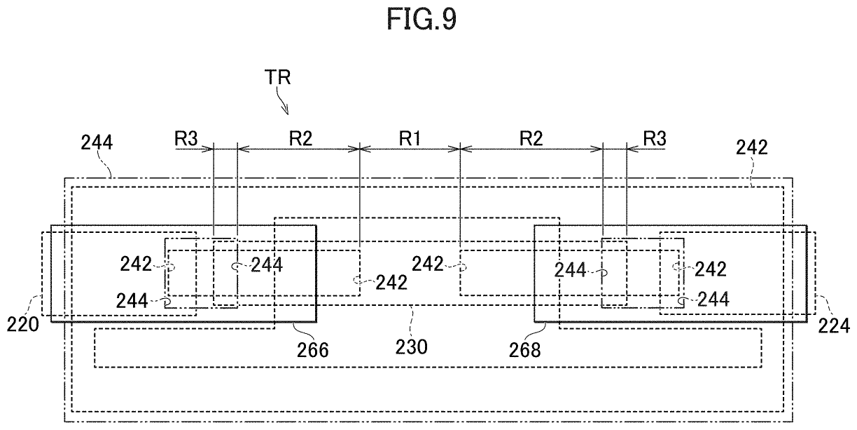

FIG. 8 is a detailed cross-sectional view of a thin film transistor TR of the display device according to a second embodiment. FIG. 9 is a detailed plan view of the thin film transistor TR.

In the embodiment, the pair of source/drain electrodes 220, 224 (source electrode, drain electrode) are positioned without overlapping with the oxide semiconductor layer 230. That is, the source/drain electrodes 220, 224 are not on the oxide semiconductor layer 230. Therefore, the ends of the source/drain electrodes 220, 224 do not exist on the oxide semiconductor layer 230. Instead, a pair of metal layers 266, 268 are on and in contact with the respective pair of third upper surface regions R3. The pair of metal layers 266, 268 are placed in contact with the respective pair of source/drain electrodes 220, 224. In the pair of third upper surface regions R3, the oxide semiconductor layer 230 is reduced and made conductive by the metal layers 266, 268.

In the manufacturing method of the display device according to the embodiment, the pair of source/drain electrodes 220, 224 are formed without overlapping with the oxide semiconductor layer 230. That is, an etching mask (not shown) is placed over the oxide semiconductor layer 230 while the source/drain electrodes 220, 224 are being formed by etching a metal film. Thus, the oxide semiconductor layer 230 is not etched. Specifically, the oxide semiconductor layer 230 tends to be uneven in the film thickness at a portion adjacent to an edge of the etching mask placed thereover, but this can be avoided in the embodiment.

The oxidizing agent layer 242 and the reducing agent layer 244 are formed except on the pair of third upper surface regions R3 sandwiching the first upper surface region R1 and the second upper surface region R2. The pair of metal layers 266, 268 are formed to be on and in contact with the respective pair of third upper surface regions R3 and to be on and in contact with the respective pair of source/drain electrodes 220, 224. What is explained in the first embodiment is applicable hereto. Incidentally, forming the pair of metal layers 266, 268 in the same layer as the second capacitance electrode 26 in FIG. 4 can avoid increase in process costs.

### Third Embodiment

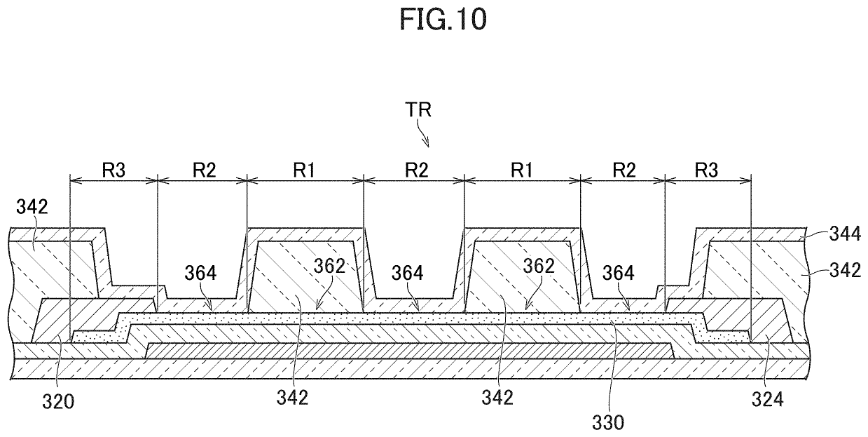

FIG. 10 is a detailed cross-sectional view of a thin film transistor TR of the display device according to a third embodiment.

In the embodiment, there are a plurality of first upper surface regions R1 separated from each other in the direction between the pair of source/drain electrodes 320, 324. The oxidizing agent layer 342 is on each of the first upper surface regions R1, oxidizing the oxide semiconductor layer 330. Thus, the oxide semiconductor layer 330 has some semiconductor portions 362 spaced from each other. The semiconductor portion 362 loses electrons by oxidation and exhibits semiconductor properties, thereby enabling transistor operation.

The second upper surface region R2 has its part between the first upper surface regions R1. The reducing agent layer 344 is placed on the second upper surface region R2 and between the adjacent first upper surface regions R1, reducing the oxide semiconductor layer 330. Thus, the oxide semiconductor layer 330 includes the conductive portion 364 reduced from the second upper surface region R2 by the reducing agent layer 344. The conductive portion 364 is made conductive by decrease in oxygen through reduction and by increase in electrons for carriers. What is explained in the first embodiment is applicable herein.

### Fourth Embodiment

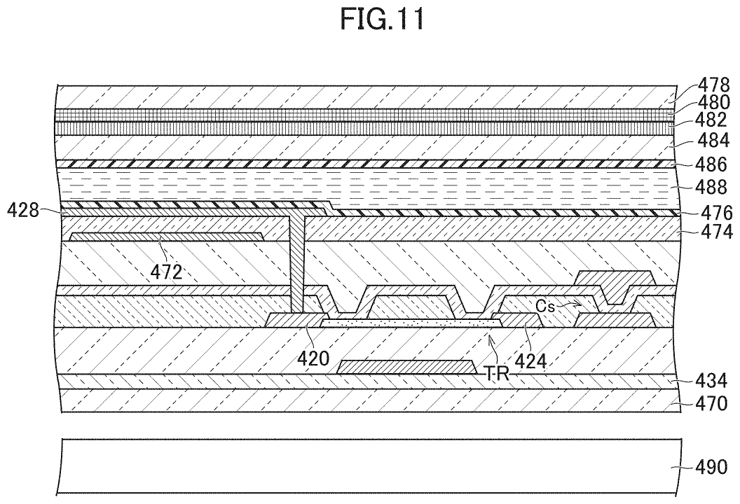

FIG. 11 is a cross-sectional view of a display device according to a fourth embodiment. The display device is a liquid crystal display device.

The display device has a glass substrate 470. The undercoat layer 434 is over the glass substrate 470 and has the thin film transistor TR thereon. The pixel electrode 428 is connected to one of the source/drain electrodes 420, 424 (one of the source electrode and the drain electrode) of the thin film transistor TR. A transverse electric field method is applied for driving the liquid crystal, with the common electrode 472 disposed below the pixel electrode 428. An insulating film 474 is interposed between them. The pixel electrode 428 has slits (not shown) formed therein. A first alignment layer 476 is laminated covering the plurality of pixel electrodes 428. The display device has a counter glass substrate 478.

The counter glass substrate 478 is equipped with a black matrix 480 and a color filter layer 482, and is covered with an overcoat layer 484 on the lower side. A second alignment film 486 is laminated covering the overcoat layer 484. In the illustrated example, the black matrix 480 is disposed between the counter glass substrate 478 and the color filter layer 482, may be disposed between the color filter layer 482 and the overcoat layer 484, or may be disposed between the overcoat layer 484 and the second alignment film 486. A liquid crystal layer 488 is interposed between the first alignment film 476 and the second alignment film 486. The cell gap is kept by unillustrated spacers.

The display device has a backlight module 490 on a side opposite to the display surface where images are displayed. The backlight module 490 includes a light source such as an LED (Light Emitting Diode), a light guide plate, an optical film, a diffuser, a reflector, and a frame. A point light is converted into a plane light by a light guide plate.

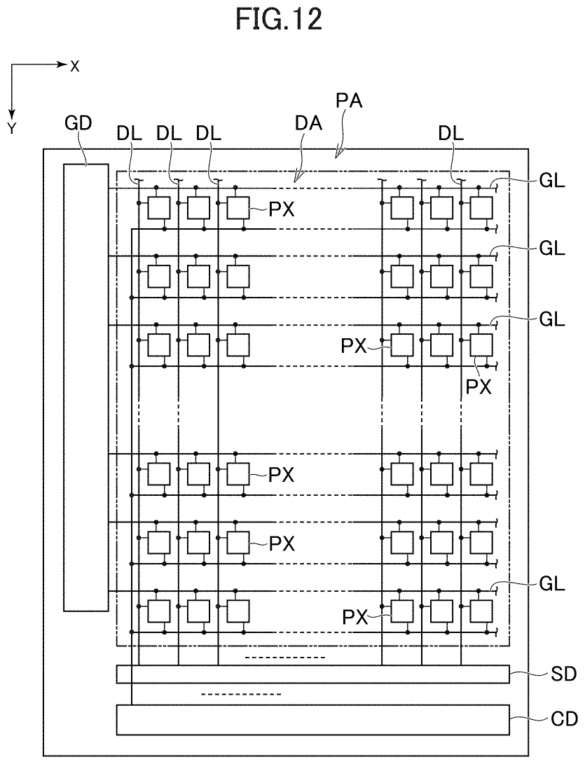

FIG. 12 is a diagram of an overall circuit of the display device. The display device includes the display area DA for displaying images, and a peripheral region PA outside the display area DA. For example, the peripheral region PA surrounds the display area DA and has a frame-like shape. The display device includes a plurality of pixels PX in the display area DA. The plurality of pixels PX are arranged in a matrix in the first direction X and the second direction Y. In the embodiment, a full color pixel is constituted by three pixels PX adjacent to each other in the first direction X.

The display device includes a plurality of scanning lines GL and a plurality of signal lines DL. The scanning lines GL extend in the first direction X and are spaced in the second direction Y. The signal lines DL extend in the second direction Y are spaced in the first direction X. Note that the scanning lines GL and the signal lines DL do not necessarily have to extend linearly, and part of each of them may be bent. The scanning lines GL are connected to the scanning circuit GD. The signal lines DL are connected to the signal drive circuit SD.

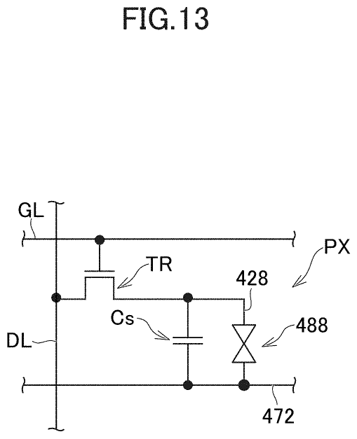

FIG. 13 is a diagram of a circuit configuration of the pixel PX in FIG. 12. The pixel PX includes a thin film transistor TR disposed near a position where the scanning line GL and the signal line DL intersects. The thin film transistor TR is electrically connected to the scanning line GL and the signal line DL. The scanning line GL is connected to the thin film transistor TR in each of the pixels PX arranged in the first direction X in FIG. 12. The signal line DL is connected to the thin film transistor TR in each of the pixels PX arranged in the second direction Y in FIG. 12.

The pixel electrode 428 is disposed in each of areas surrounded by the scanning lines GL and the signal lines DL. The thin film transistor TR is electrically connected to the pixel electrode 428. The pixel electrode 428 is opposed to the common electrode 472 and is configured to drive the liquid crystal layer 488 by an electric field generated between the pixel electrode 428 and the common electrode 472. The common electrode 472 is connected to the common drive circuit CD in FIG. 12, and is disposed over the plurality of pixels PX. Both ends of the holding capacitor Cs are electrically connected to the common electrode 472 and the pixel electrode 428.

While there have been described what are at present considered to be certain embodiments, it will be understood that various modifications may be made thereto, and it is intended that the appended claims cover all such modifications as fall within the true spirit and scope of the invention.

What is claimed is:

1. A display device comprising a plurality of thin film transistors configured to control displaying images, each of the plurality of thin film transistors being of a bottom gate type and including:
a gate electrode;
a gate insulating film covering the gate electrode;
an oxide semiconductor layer on the gate insulating film;
a silicon oxide in contact with a first upper surface region of the oxide semiconductor layer;
a silicon nitride in contact with a second upper surface region of the oxide semiconductor layer; and
a source electrode and a drain electrode above the gate insulating film,
wherein
the second upper surface region is adjacent to each of both sides of the first upper surface region in a direction between the source electrode and the drain electrode, and
the oxide semiconductor layer includes a semiconductor portion directly below the silicon oxide and a conductive portion directly below the silicon nitride.

2. The display device according to claim 1, wherein
the silicon oxide is an oxidizing agent layer, and
the silicon nitride is a reducing agent layer containing hydrogen.

3. The display device according to claim 1, wherein
the oxide semiconductor layer has a pair of third upper surface regions sandwiching the first upper surface region and the second upper surface region, and
the source electrode and the drain electrode are electrically connected to the respective pair of third upper surface regions.

4. The display device according to claim 3, wherein the source electrode and the drain electrode are placed on and in contact with the respective pair of third upper surface regions.

5. The display device according to claim 4, wherein
the source electrode and the drain electrode are made of metal, and
the oxide semiconductor layer, in the pair of third upper surface regions, is reduced by the metal.

6. The display device according to claim 3, wherein the source electrode and the drain electrode are positioned without overlapping with the oxide semiconductor layer,
the display device further comprising a pair of metal layers placed on and in contact with the respective pair of third upper surface regions, the pair of metal layers placed on and in contact with the source electrode and the drain electrode, respectively.

7. The display device according to claim 6, wherein the oxide semiconductor layer, in the pair of third upper surface regions, is reduced by the metal layer.

8. The display device according to claim 1, wherein
the first upper surface region includes some first upper surface regions separated from each other in the direction between the source electrode and the drain electrode, and
part of the second upper surface region is interposed between the first upper surface regions.

9. The display device according to claim 1, wherein the silicon oxide is also on the source electrode and the drain electrode.

10. The display device according to claim 9, wherein the silicon nitride is also on the silicon oxide.

11. The display device according to claim 1, wherein the gate electrode overlaps with none of the source electrode and the drain electrode.

12. A method of manufacturing a display device, the method comprising:
forming a gate electrode;
forming a gate insulating film to cover the gate electrode;
forming an oxide semiconductor layer on the gate insulating film;
forming a source electrode and a drain electrode, through deposition and etching on the oxide semiconductor layer, except in the first upper surface region and the second upper surface region of the oxide semiconductor layer;
forming an oxidizing agent layer in contact with the first upper surface region of the oxide semiconductor layer, and oxidizing the oxide semiconductor layer in the first upper surface region; and
forming a reducing agent layer in contact with the second upper surface region of the oxide semiconductor layer, and reducing the oxide semiconductor layer in the second upper surface region,
wherein the second upper surface region is adjacent to each of both sides of the first upper surface region in a direction between the source electrode and the drain electrode.

13. The method of manufacturing the display device according to claim 12, wherein the etching is performed using a chlorine-based gas.

14. The method of manufacturing the display device according to claim 12, wherein the formation of the oxidizing agent layer includes dry etching using a fluorine-based gas.

15. The method of manufacturing the display device according to claim 12, wherein in the process of forming the oxidizing agent layer, the oxidizing agent layer is formed also on the source electrode and the drain electrode.

16. The method of manufacturing the display device as claimed in claim 15, wherein in the process of forming the reducing agent layer, the reducing agent layer is formed also on the oxidizing agent layer.

17. The method of manufacturing the display device according to claim 12, wherein
the source electrode and the drain electrode are formed without overlapping with the oxide semiconductor layer, and
the oxidizing agent layer and the reducing agent layer are formed, except on a pair of third upper surface regions sandwiching the first upper surface region and the second upper surface region,
the method further comprising forming a pair of metal layers, on and in contact with the respective pair of third upper surface regions, and on and in contact with the source electrode and the drain electrode, respectively.
